(19) United States
(12) Patent Application Publication
(10) Pub. No.: US 2017/0011574 A1
(43) Pub. Date: Jan. 12, 2017

(54) ELECTRONIC TAMPER RESISTANT LOAD CONTROL

(71) Applicant: Leviton Manufacturing Company, Inc., Melville, NY (US)

(72) Inventor: Marc Noest, Westbury, NY (US)

(21) Appl. No.: 14/796,673

(22) Filed: Jul. 10, 2015

(51) Int. Cl. G07C 9/00; H05K 5/02; H05K 5/06

(52) U.S. Cl. CPC G07C 9/00896; H05K 5/06; H05K 5/0239; G07C 2009/00769

(57) ABSTRACT

A system comprising an access token to communicatively couple with an access control module enclosed in a housing and wirelessly communicate identification information to the access control module. The access control module for receiving the identification information from the access token and facilitating validation of the identification information. The access control module is also communicatively coupled with a load control module. The load control module configured to control an operational state of an associated load and to enable the access token, upon validation of the identification information, to alter the operational state of the associated load.

### FIELD OF THE DISCLOSURE

The present disclosure relates generally to load control devices, and more particularly to an electronic tamper resistant load control switching device.

### BACKGROUND OF THE DISCLOSURE

Tamper resistant electrical switches can be used to prevent access and operation by unauthorized individuals. In one example, tamper resistant electrical switches can include locked covers that completely enclose the switch, making it inaccessible to a user that does not have a key to unlock the cover. Other types of tamper resistant electrical switches include mechanical key-operated arrangements in which a specially designed key can be fit through a recess or opening in the housing. The key can then be used to engage the switch to operate an associated load. In some cases, the mechanical key includes special mechanical profile that engages corresponding features inside the housing so that by moving the key, the switch can be operated to activate or deactivate an associated load such as a light. Individuals without the specially designed mechanical key either cannot access the switch, or if they can access the switch they cannot actuate it. Such arrangements have served to successfully prevent unauthorized operation of a connected load.

One deficiency with current arrangements is that such key-based tamper resistant technology is mechanical in nature. Many of these devices are “keyed” the same way, so once a user secures a key, that key can then be used with any of a variety of switches, regardless of whether the user is authorized to operate the switch. Further, generic keys make it impossible to monitor and record the operation of a tamper resistant load control system.

Accordingly, it is desirable to provide a secure tamper resistant load control system with the ability to add and remove one or more user credentials. Achieving additional control over critical loads by tracking the operation of the tamper resistant load control system is also desirable. It is further desirable to simplify installation while reducing maintenance by providing wireless operation with durable electronic system components.

### SUMMARY OF THE DISCLOSURE

A load control system is disclosed, including an access token, an access control module, and a load control module. The access control module may be enclosed in a housing. The access token may be configured to wirelessly communicate identification information to the access control module. The access control module may be configured to receive the identification information from the access token and validate the identification information. The access control module may be communicatively coupled with the load control module. The load control module may be configured to control an operational state of an associated load. The load control module may be configured to enable the access token, upon validation of the identification information, to cause the operational state of the associated load to alter. The load control module may be communicatively coupled to the access control module.

A wirelessly controlled load control device is disclosed, including a housing having an access control module disposed therein. The access control module may be configured to control an operational state of an associated load. An access token may be associated with a user. The access control module may be wirelessly communicable with the access token. A load status indicator may be associated with the housing for indicating the operational state of the associated load.

A method is disclosed for remotely controlling the operational state of a load, including: radiating electromagnetic energy from an access control module enclosed in a housing; interrogating an access token with the radiated electromagnetic energy, the interrogating causing the access token to reradiate electromagnetic energy, the reradiated electromagnetic energy including an analog signal comprising identification information; receiving the reradiated electromagnetic energy at the access control module; receiving, by a processor, the identification information from the analog signal included in the reradiated electromagnetic energy; and altering an operational state of an associated load based on the received identification information.

### BRIEF DESCRIPTION OF THE DRAWINGS

By way of example, exemplary embodiments of the disclosed device will now be described, with reference to the accompanying drawings, in which:

FIG. 1 is an overview of an exemplary embodiment of a load control system;

FIG. 2 is bock diagram of an exemplary embodiment of an access token;

FIG. 3 is a block diagram of an exemplary embodiment of an access control module;

FIG. 4 is a block diagram of an exemplary embodiment of a load control module coupled to a power supply and an associated load;

FIG. 5A is block diagram of an exemplary embodiment of a wired control link between an access control module and a load control module;

FIG. 5B is block diagram of an exemplary embodiment of a wired control link including a management module between an access control module and a load control module;

FIG. 6A is block diagram an exemplary embodiment of a wireless control link between an access control module and a load control module;

FIG. 6B is block diagram of an exemplary embodiment of a wireless control link including a management module between an access control module and a load control module;

FIG. 7A is an exemplary embodiment of a load control system wherein a load is located proximate both to a load control module and to an access control module within a housing;

FIG. 7B is an exemplary embodiment of a load control system wherein a load is located separate from both a load control module and an access control module within a housing;

FIG. 8 is an exemplary embodiment of a load control system wherein a load is located distant from an access control module within a housing, and a load control module is located proximate the load; and

FIG. 9 is a logic diagram illustrating an exemplary method of operation of disclosed the load control system.

### DETAILED DESCRIPTION

The following disclosure is intended to provide exemplary embodiments of the disclosed system and method, and these exemplary embodiments should not be interpreted as limiting. One of ordinary skill in the art will understand that the steps and methods disclosed may easily be reordered and manipulated into many configurations, provided they are not mutually exclusive. As used herein, “a” and “an” may refer to a single or plurality of items and should not be interpreted as exclusively singular unless explicitly stated.

In general, a wirelessly controllable load control system is disclosed for changing the operating status of a load (e.g., light, fan, or the like) without the need for a mechanical key. The disclosed system can include an access token that can wirelessly communicate with an access control module to activate or deactivate a load via a load control module. Such a wirelessly controllable system can be employed to allow only authorized users to control the on/off state of a load. In some embodiments the access control module can store a variety of information regarding the operation of the load. For example, the access control module may store information about how often the load is on or off, which user commanded the on/off cycle, and the like. In addition, because each authorized user may have a unique access token, the access control module can be accessed by a system administrator, for example, to update an access list to authorize new users, de-authorizing certain users and the like.

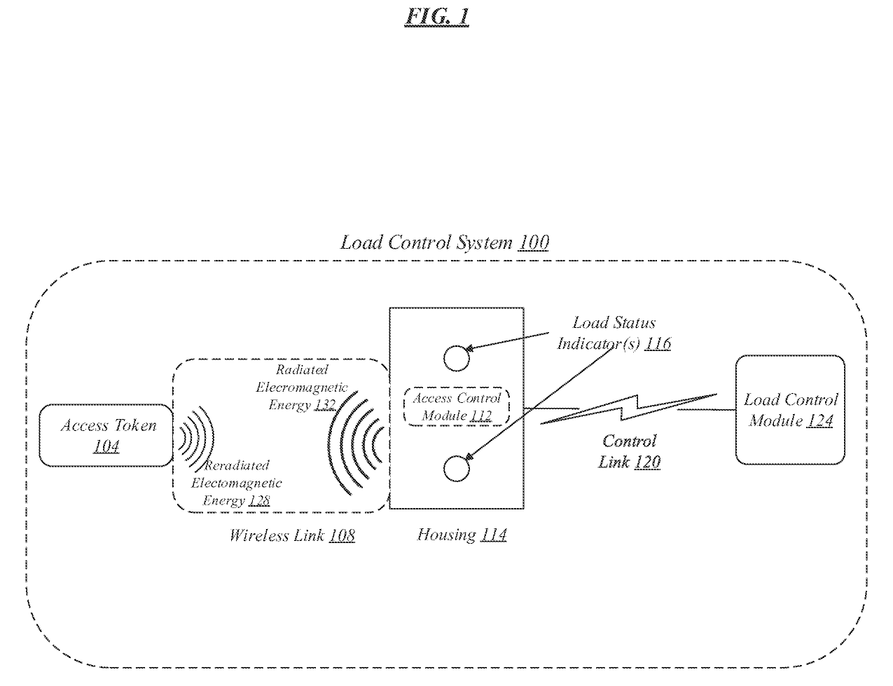

Referring now to FIG. 1, an exemplary embodiment of the disclosed load control system 100 is shown. In general, the load control system 100 includes an access token 104 for wirelessly communicating with an access control module 112, which in turn communicates with a load control module 124 to control the operational state of an associated load, such as but not limited to a light, a fan, a pump, or the like. The access control module 112 can reside within a housing 114, which in one exemplary non-limiting embodiment is a tamper resistant housing. In some embodiments the housing 114 may be configured to be mounted in a standard electrical wall box (not shown).

The illustrated embodiment of the housing 114 may include one or more load status indicators 116. One of ordinary skill in the art will appreciate that one or more load status indicators 116 may be located exterior to the housing 114. These exterior load status indicators 116 may be placed a plurality of arrangements provided the load status indicator 116 is proximate to the housing 114 (in other embodiments, load status indicator 116 may not be proximate to the housing 114). As used herein, proximate to the housing means that the load status indicator 116 is perceivable by a user located at or near the housing 114. The load status indicators 116 may demonstrate to a user the state (i.e., on/off status) of a connected load. This can be accomplished in any manner or manners sufficient to make a user cognizant of the status of the associated load, including using visual, audible, or tactile signals, or combinations thereof. In one non-limiting exemplary embodiment, the load status indicators 116 may be light emitting diodes (LEDs).

In the illustrated embodiment, two load status indicators 116 are coupled to the housing 114. An ‘ON’ state of the associated load may be indicated by a LED emitting flashing or solid light of a first color, and an ‘OFF’ state may be indicated by a LED emitting flashing or solid light of the first color or a second color. In alternative embodiments the housing 114 may include a single LED load status indicator 116 or more than two LED load status indicators 116. In some embodiments, the status of the associated load may be communicated by altering the brightness and/or color of one or more LED load status indicators 116. The brightness and/or color of one or more LEDs may be systematically varied to produce a pattern of variations in the LED brightness. The LED brightness may be controlled digitally (or by any suitable method).

In some embodiments, labeling may be used in or on the housing 114 to indicate how to interpret the appearance of the load status indicators 116. Additionally, such labeling may be incorporated into the load status indicator 116 itself. For example, the load status indicator 116 can comprise lighting of static lettering. In some embodiments, the load status indicator 116 may include a user interface. The user interface may include a graphical user interface (GUI), such as a display screen, which can be a liquid crystal display (LCD), a touch screen or the like. If the load status indicator 116 is a touch screen, it may be configured to be manipulated by a user to monitor and change the state of one or more associated loads.

In certain embodiments, the load status indicator 116 may comprise an audible signal, such as may be provided by a speaker, piezoelectric element, and/or buzzer (not shown) positioned within or proximate to the housing 114. Such an audible signal may provide one or more signals indicating the status of the associated load. In one example, the audible signal may comprise tones or beeps. Also, the audible signal may include a recorded or computer-generated voice stating the status of the load.

The access control module 112 may communicatively couple via a wireless link 108 with the access token 104 through one or more methods of automatic identification and data capture (AIDC). In one embodiment, the wireless link 108 may be initiated by radiated electromagnetic energy 132 originating from the access control module 112. The access token 104 may, in some embodiments, derive energy from the radiated electromagnetic energy 132 to produce reradiated electromagnetic energy 128 in response to a communication by the access control module 112. The reradiated electromagnetic energy may include an analog signal comprising identification information.

In other embodiments, the wireless link 108 can be initiated by radiated electromagnetic energy originating from the access token 104. In order for the access token 104 to initiate the wireless link 108, the access token 104 should derive at least some of its power from sources other than electromagnetic energy originating from an external source like the access control module 112. Thus, the access token 104 may include a battery, such as a Lithium ion battery.

One having ordinary skill in the art will appreciate that various encryption and security features can readily be incorporated into any mode of communication between the access token 104 and the access control module 112.

In one non-limiting example, wireless communications within the disclosed load control system 100 can include any of a variety of appropriate radio-frequency identification (RFID) techniques including, but not limited to, near field communication (NFC) techniques. These configurations can include a tag and a reader. In exemplary embodiments, the access token 104 may comprise the tag and the access control module 112 may comprise the reader. These embodiments can be configured in a variety of arrangements as will be understood by one of ordinary skill in the art.

In one arrangement, sometimes known as an active reader passive tag (ARPT) system, the reader may communicate with the tag by sending signals to it. The tag derives energy from the signals sent by the reader and uses the energy to respond to the reader with identification information. In another arrangement, often referred to as an active reader active tag (ARAT) system, the reader sends a signal to the tag requesting a return signal including identification information. The tag receives the signal and replies to the signal using an internal energy source. In a third arrangement, known as a passive reader active tag (PRAT) system, the tag uses an internal energy source to send a signal to a passive reader. This signal can comprise identification information. The passive reader only receives signals and does not send signals to the tag. Alternative embodiments may make use of a personal area network (e.g. Bluetooth), a barcode, or biometric technologies.

The access control module 112 may communicate with a load control module 124 to energize, de-energize or otherwise adjust operation of an associated load. In the illustrated embodiment this communication is illustrated as control link 120. The control link 120 may be facilitated using any of a variety of technologies, which will be described in more detail below. As will be appreciated, the load control module 124 can also employ different communications technologies to control an associated load. Such arrangements will also be discussed in greater detail below.

As noted, the housing 114 may be a tamper resistant housing constructed of one or more materials possessing sufficient mechanical properties to resist tampering and the ingress of moisture, dirt, sand or other contaminants associated with weathering or harsh environments. In one embodiment, the housing 114 may be constructed of steel coated in a protective polymer, although this is not limiting, and the housing can be made from any material appropriate for protecting the contents housed therein. In one embodiment, the housing can be composed of one or more components including but not limited to ports, doors, openings, and assembly pieces. In addition, a gasket (not shown) may be used to ensure the integrity of the seal between abutting components.

The housing 114 can include an interior cavity for receiving the access control module 112 therein. The cavity within the housing 114 can be accessed by authorized users to allow for any necessary repairs, replacements, reconfigurations, etc. In one embodiment, the cavity within the housing 114 is sealed with one or more security or tamper proof screws such as, but not limited to, spanner, center pin hex, center pin or security 6 point star, one-way, breakaway head screws (or any other suitable fasteners).

The housing 114 can be mounted to any structure appropriate for facilitating the control of one or more loads as will be described herein. For example, the housing 114 can be mounted in or on a static structure such as an interior or exterior wall of a building associated with the load that will be controlled. Alternatively, the housing 114 can be mounted in a control panel area associated with a building security system, or the like. The static structure, as used herein, is any object that cannot be moved unless the structure is disassembled in one or more manners; or the structure cannot be lifted by an individual absent a mechanical advantage. For example, a post with one end buried into ground and removable concrete barricades are considered static structures.

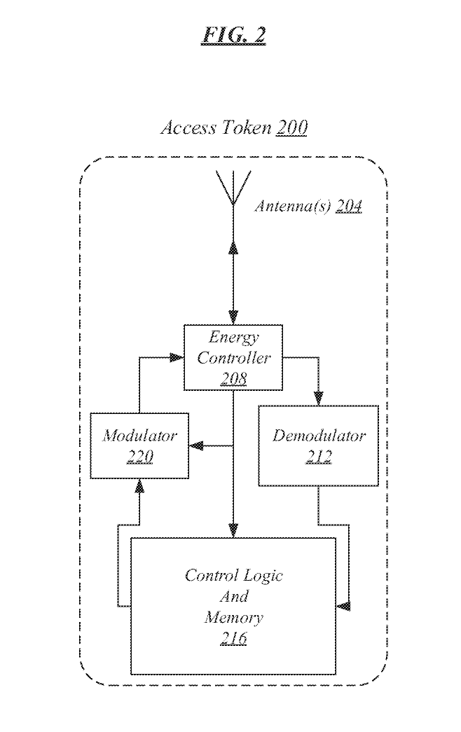

FIG. 2 is a bock diagram of an exemplary embodiment of an access token 200 for use with the load control system 100. (It will be appreciated that the access token 104 of FIG. 1 may include any or all of the features of the access token 200 of FIG. 2.) The operation of the access token 200 can include wirelessly providing credentials to an access control module 112 (FIG. 1) for validation and for causing the state of an associated load to be altered and/or displayed. In one embodiment the access token 200 may cause the state of the associated load to be altered and/or displayed upon the access token 200 being positioned within an activation region of the access control module 112. The activation region may be a region proximate to the access control module 112 that enables the access control module 112 to communicate with the access token 200. In some embodiments, the access token 200 may derive energy for operation from one or more sources including a wireless source of radiated electromagnetic energy (such as from the access control module 112) or a wired power source (such as an internal battery). In some embodiments the access token 200 may receive electromagnetic energy through an antenna 204. The antenna 204 may act as a transducer by converting radiated electromagnetic energy into conducted electrical signals (or vice versa).

In the illustrated embodiment the access token 200 can derive energy for operation from the radiated electromagnetic energy 132 originating from the access control module 112 (see FIG. 1). The antenna 204 can take electromagnetic radiation and make it available to the energy controller 208 in the form of conducted electrical signals. The energy controller 208 may condition and store the conducted electrical signals received from the antenna 204 in order to provide other components of the access token 200 with sufficient power to operate. The energy controller 208 may also control and alter its input impedance as will be described further below.

The access token 200 can further include a demodulator 212. The demodulator 212 may extract an original message-bearing digital signal from a modulated carrier wave, which in one embodiment is included in the radiated electromagnetic energy 132 emanating from the access control module 112. The extracted message-bearing digital signal can then be passed to a control logic and memory 216.

The control logic and memory 216 can process the digital signal and output a digital signal containing data stored in its memory (alternatively, the data may not need to be stored in its memory). The memory in the access token can be any suitable memory component, which in one non-limiting exemplary embodiment is a solid state memory component. In the illustrated embodiment, the control logic and memory 216 can generate a digital signal containing identification information for validation by the access control module 112.

The access token 200 can further include a modulator 220. In the depicted embodiment, the modulator 220 can take the digital signal output from the control logic and memory 216 and apply backscatter modulation techniques to alter the input impedance of the energy controller 208. The mismatch in impedance can cause some power to reflect back through the antenna and scatter as reradiated electromagnetic radiation 128 (FIG. 1). The reradiated electromagnetic energy can include an analog signal comprising identification information. The identification information may comprise a set of credentials. Control over the input impedance of the energy controller 208 may allow reradiated electromagnetic radiation 128 to convey information to the access control module 112. In the illustrated embodiment, the input impedance of the energy controller 208 can be altered in a manner that conveys identification information stored in the memory of the access token 200. The identification information stored in the memory of the access token 200 can comprise the aforementioned credentials.

In some embodiments one or more elements of the access token 200 can be placed or combined on an integrated circuit (IC). The access token 200 can also be either read-write (R/W) or read-only (R/O). R/W access tokens can have high voltage charge pump circuitry in the energy controller 208 to provide a higher level of power that is required for the write operation in the memory of the control logic and memory 216. R/W access tokens can allow a user with the appropriate equipment to alter the contents of the memory in the access token 200. Although the contents of memory on R/O access tokens cannot be altered, the memory components of R/O access tokens are simpler and more energy efficient than R/W access tokens.

The access token 200 can be placed inside a housing to protect components from damage and unauthorized access. This housing may be one and the same as a housing for another device such as a mobile phone. Further, the access token housing may have one or more features allowing the access token 200 to be attached to one or more other objects. For example, the one or more features of the access token 200 can enable the access token 200 to be attached to a key ring, a belt or belt loop, a flashlight, or an article of clothing. Additionally, the shape of the access token housing may allow for storage of the access token in various locations, such as but not limited to, a wallet or a pocket.

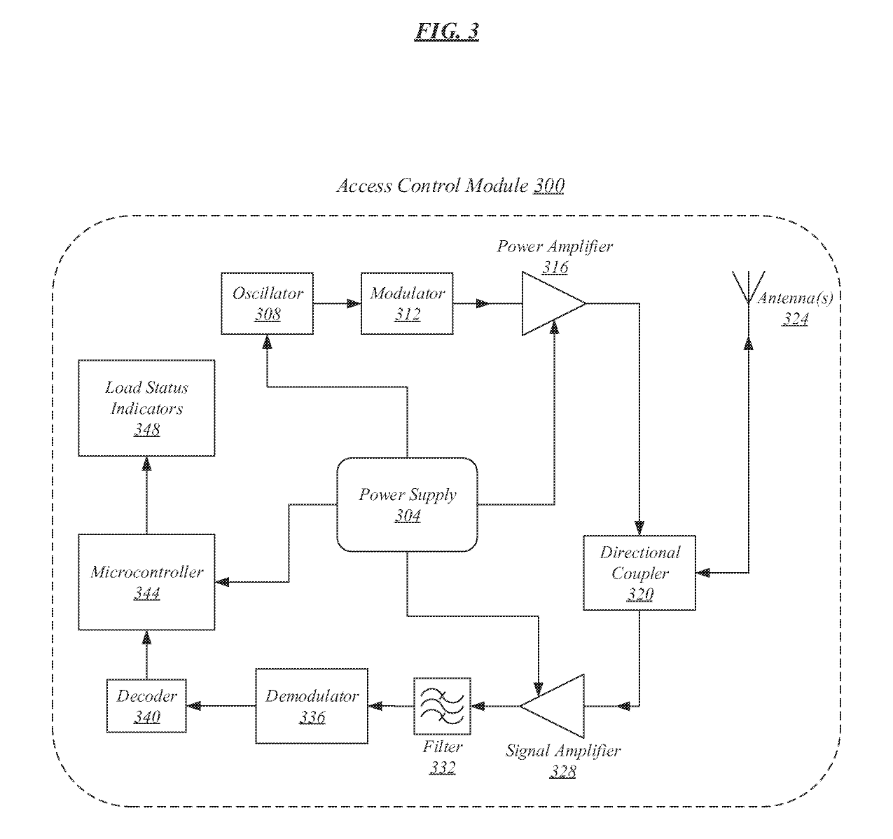

FIG. 3 is a block diagram of an exemplary embodiment of an access control module 300. (It will be appreciated that the access control module 112 of FIG. 1 may include any or all of the features of the access control module 300 of FIG. 3, and thus the access control module 300 may be housed within the housing 114.) The access control module 300 can function to receive a set of credentials from the access token 104, 200, determine if the received set of credentials match a predetermined criteria, display the state of an associated load, and/or alter the state of the associated load accordingly (e.g., turn the load on or off or change the intensity or other setting of the load). The change in or display of state of the associated load may be instigated by the access control module 300 locating the access token 104, 200 within the activation region.

In the illustrated embodiment, the components of the access control module 300 can receive power from a power supply 304 and function in a manner implemented by a microcontroller 344. An oscillator 308 can generate a periodic, oscillating electronic signal, also known as a carrier wave. In some embodiments, the generation of the carrier wave may be initiated by one or more motion sensors (not shown) located proximate the housing 114 (or may be initiated by any other suitable means). The carrier wave can be modulated, at modulator 312, with an input signal. The input signal can contain information for conveyance to the access token 104, 200. A power amplifier 316 can then amplify the modulated carrier wave to levels sufficient for the access token 104, 200 to derive operational energy from the modulated carrier wave. The amplified modulated carrier wave can then be routed by a directional coupler 320 into an antenna 324 for transmission.

In the illustrated embodiment, the antenna 324 can receive reradiated electromagnetic energy 128 (FIG. 1) from the access token 104, 200. In some embodiments the antenna may act as a transducer by converting the reradiated electromagnetic energy 128 into conducted electrical signals (or vice versa). The directional coupler 320 can route the conducted electrical signals into a signal amplifier 328. The signal amplifier 328 may be a low noise amplifier that amplifies the conducted electrical signals with little signal degradation. The amplified conducted electrical signals are then passed through a filter 332 to remove undesirable components from the amplified conducted electrical signals. A demodulator 336 can then extract identification information, which may comprise a set of credentials from the reradiated electromagnetic energy 128 in the form of a digital signal. A decoder 340 may then convert the digital signal into a format that microcontroller 344 can interpret.

The microcontroller 344 may serve as the command and control device for the components of the access control module 300. The microcontroller 344 also can be communicatively coupled to the control link 120 (FIG. 1). In some embodiments the control link 120 can comprise a local area network (LAN). In other embodiments the LAN can be communicatively coupled to one or more wide area networks (WAN). In one embodiment, the microcontroller 344 can access an authorization data structure to validate the set of credentials provided by the access token 104. In one non-limiting exemplary embodiment, such a data structure can be stored in memory associated with the microcontroller 344. In some embodiments, the microcontroller 344 may transmit the set of credentials over the control link 120 for validation. The microcontroller 344 can also receive a response to the validation query over the control link 120. In either case, upon validation of the identification information, the microcontroller 344 can activate the load status indicators 116, 348 to communicate the activation status of the associated load to the user. In some embodiments, upon validation of the identification information, the microcontroller 344 may alter the state of the associated load. In other embodiments, the microcontroller 344 may alter the state of the associated load and may display the state of the load upon validation of the identification information. In other embodiments, the status of the load or the load itself may be displayed and/or changed based on the identification information. For example, certain functions may be available or not available based on which user is requesting access.

Embodiments are also contemplated in which the control link 120 comprises a wire coupled between the access control module and the associated load. For example, if the access control module determines that the access token is “authorized,” the access control module energizes the wire so that 120 VAC, for example, can be delivered directly to the load.

For embodiments in which a GUI is provided (e.g., LCD screen, touch screen), validation of the set of access credentials may activate the GUI, and the GUI may enable a user to monitor and control the state of the associated load.

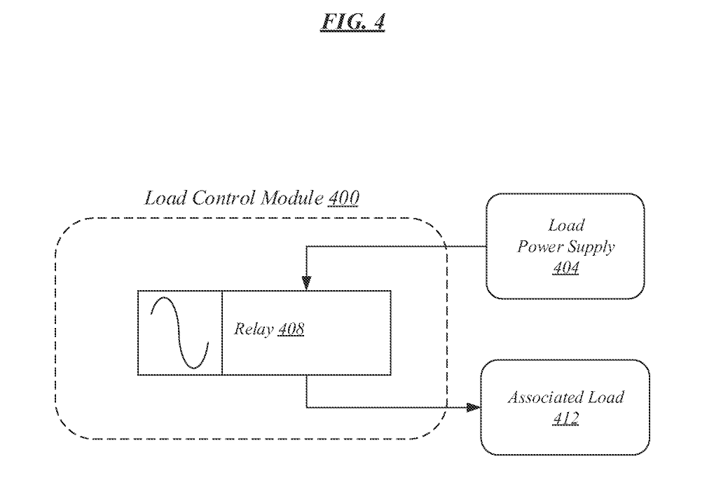

FIG. 4 is a block diagram of a depicted embodiment of a load control module 400 coupled to a load power supply 404 and an associated load 412. (It will be appreciated that the load control module 124 of FIG. 1 may include any or all of the features of the load control module 400 of FIG. 4.) As previously described, the access control module 112, 300 may be communicatively coupled to the load control module 124, 400 through control link 120 (FIG. 1). The load control module 400 can include a relay 408. The relay can be electrical or electromechanical. Where the relay is an electrical relay, it can include an integrated circuits (IC) and/or a reed switch, or any other suitable component(s).

The load control module 400 may be directly responsible for controlling the amount of power reaching the associated load 412 from the load power supply 404. In some embodiments, the load control module 400 may be a Power-Pack such as Leviton Cat. No. PE300 or control circuitry such as found in Leviton Cat. No. VPI06. The load control module 400 can be communicatively coupled with the access control module 112, 300 through the control link 120 (FIG. 1). In certain embodiments, the control link can comprise a LAN, though this is not limiting, and any other type of wired and/or wireless control links 120 can be employed. In some embodiments each of a plurality of load control modules can be assigned a unique identifier such as an internet protocol (IP) address. The unique identifier may be stored in a load control module data structure.

In some embodiments, the load control module 400 can provide dynamic and continuous control of the associated load 412. In other embodiments, the load control module 400 can provide two or more discrete load states, such as ‘OFF’, ‘STANDBY’, and ‘ON’. Further, the access control module 112, 300 may monitor and control the state of the associated load 412 by controlling the load control module 400. The associated load 412 can be any device that is electrically operated, including but not limited to lights, fans, pumps, HVAC equipment, and entertainment equipment. In some embodiments, the load power supply 404 can provide alternating current (AC) power to the associated load 412. In other embodiments the load power supply 404 can provide direct current (DC) power to the associated load 412.

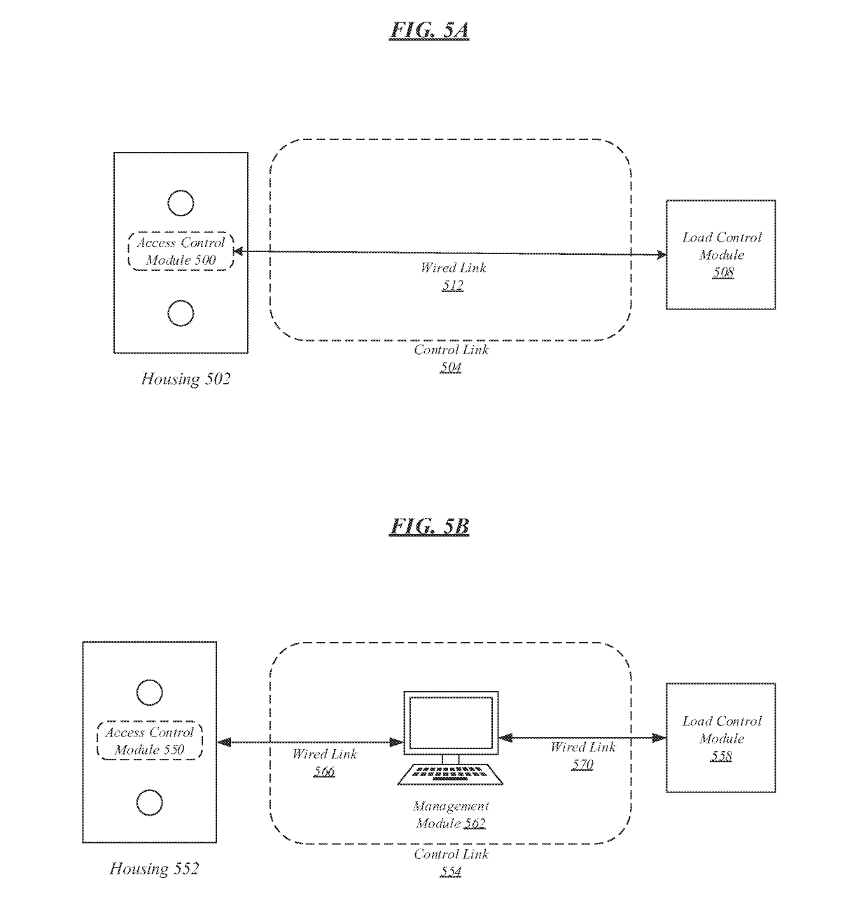

Referring now to FIGS. 5A and 5B, embodiments of the control link 120 between an access control module 112, 300 and a load control module 124, 400 will be described in greater detail. FIG. 5A shows an embodiment of a control link 504 comprising a wired link 512 between an access control module 500 and a load control module 508. The wired link 512 enables the access control module 500 within a housing 502 to monitor and control the load control module 508. FIG. 5B shows an embodiment of a control link 554 including a management module 562 coupled between the access control module 550 within a housing 552 and the load control module 558 via a pair of wired links 566, 570. The management module 562, which in the illustrated embodiment comprises a computer, can communicate with the access control module 550 through wired link 566, and can communicate with the load control module 558 through wired link 570. Communications facilitated by the control link 554 can enable the access control module 550 inside the housing 552 to monitor and control the load control module 558. By employing a management module 562, an authorized user such as a system administrator can control accessibility functions of the access control module 550, such as authorizing or de-authorizing access tokens 104, 200, limiting the loads and/or functions that a particular access token is authorized to control and the like. The management module 562 can also be used to upload/transmit historical information to another device such as the amount of time a particular load has been energized, the time of day the load is energized and de-energized, and which token (user) operated the load. All such activities can be achieved by the management module 562 in communication with the microcontroller 344 and/or the associated memory of the access control module. In addition, the management module 562 can be communicatively coupled to a local network to transmit information to a building control system or to allow wireless access by a user. Alternatively, the management module 562 can be communicatively coupled to a remote network, a wide-area network (WAN), a cellular network, or any other suitable network(s).

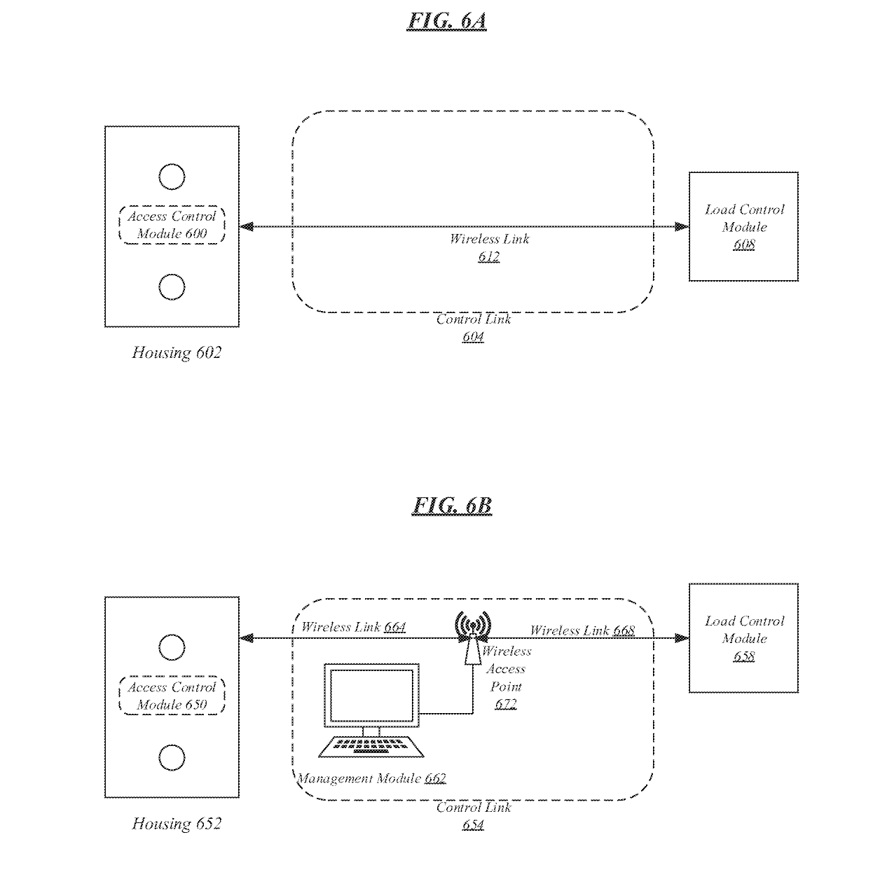

Referring now to FIGS. 6A and 6B, further embodiments of the control link 120 between an access control module 112, 300 and a load control module 124, 400 will be described in greater detail. FIG. 6A shows an embodiment of a wireless control link 604 between an access control module 600 and a load control module 608. The wireless control link 604 can include a wireless link 612 that enables the access control module 600 within the housing 602 to monitor and control the load control module 608. FIG. 6B shows an embodiment of a wireless control link 654 including a management module 662 disposed between the access control module 650 and the load control module 658. The management module 662, which in the illustrated embodiments comprises a computer, may be communicatively coupled to a wireless access point 672 which facilitates communication between the management module 662, the access control module 650 and the load control module 658 through respective wireless links 664 and 668. Communications facilitated by the wireless control link 654 may enable the access control module 650 within the housing 652 to monitor and control the load control module 658.

In some embodiments, the management module 562, 662 may include a processor and a machine readable storage medium, such as a non-volatile memory element. The machine readable storage medium may include an authorization data structure composed of identification information such as a plurality of valid sets of credentials. The plurality of valid sets of credentials may correspond to an associated plurality of access tokens 104, 200. The management module 562, 662 may validate identification information at least in part by comparing identification information received from an access control module 112, 300 to the contents of the authorization data structure. As previously noted, this identification information can be used to selectively enable or disable one or more access tokens 104, 200 so that only those tokens authorized to operate the associated load can be used. It will be appreciated by one of ordinary skill in the art that various kinds of access programs can be implemented in this manner, such as limiting the time of day in which the load can be operated, or limiting the time of day that a particular user can operate the load, and the like.

In some embodiments the management module 562, 662 may associate received identification information with a time of day, and may use this association to create a data entry in an access history data structure each time a particular access token 104, 200 communicatively couples with an access control module 112, 300. The data entry in the access history data structure can, in some embodiments, include a present state of the load (e.g., on, off, standby).

The management module 562, 662 may also be configured to receive instructions from one or more user interfaces. In some embodiments, the user interface can comprise a GUI which may enable a user to add or remove at least one of the plurality of valid sets of one or more credentials.

It will be appreciated by one having ordinary skill in the art that the control link arrangements described in FIGS. 5A-6B can be readily combined or modified. For example, an access control module may communicate with a management module through a wireless link while the management module communicates with the load control module over a wired link. Further, multiple modes of communication may be used to provide redundant or backup communication channels. In certain embodiments the access control module, the management module, and the load control module can communicate directly; in other embodiments, communication between two of the modules can be facilitated by the third module or a network infrastructure.

The wired links can be any appropriate technology, including Ethernet, line voltage, low voltage, twisted pair, or the like. Alternative embodiments may include fiber optic links. The wireless links can be any appropriate wireless technology, including Wi-Fi, personal area network (e.g. Bluetooth).

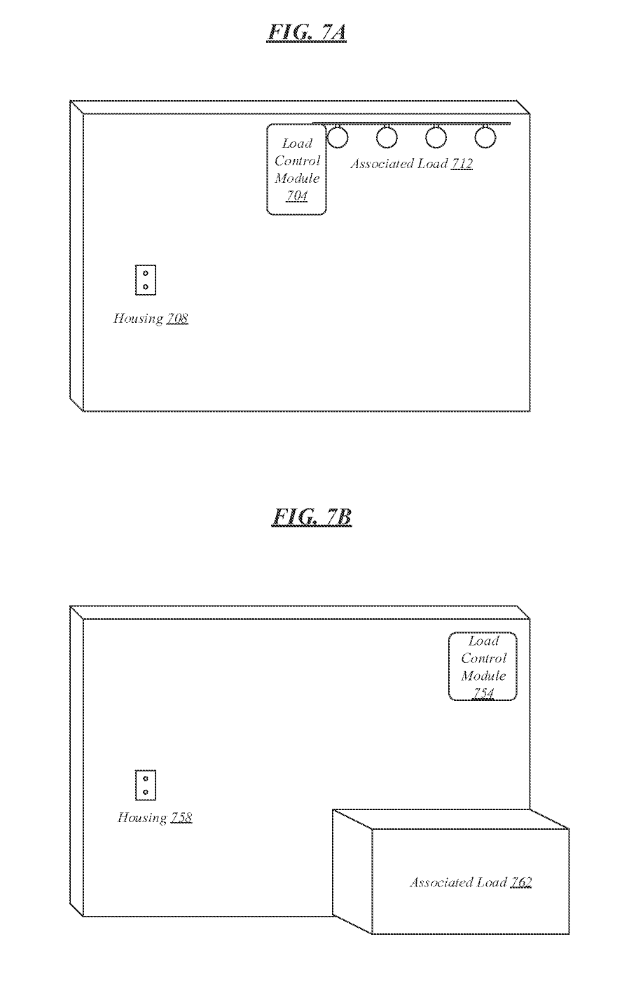

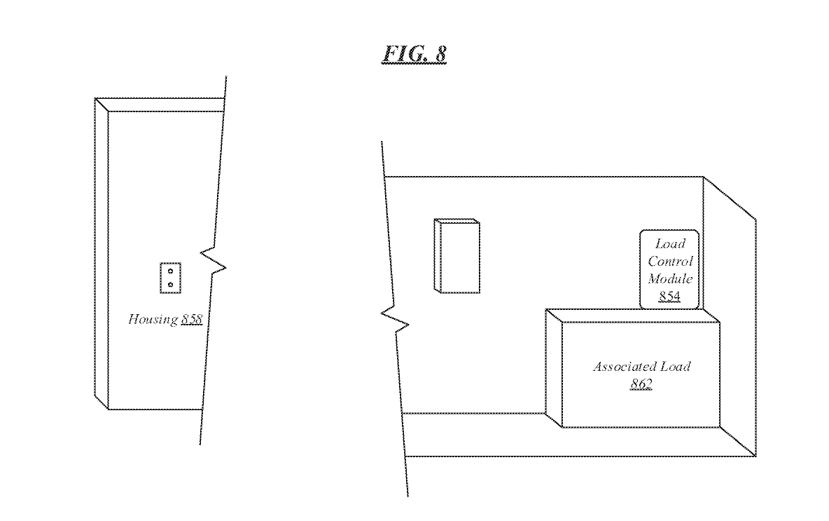

FIGS. 7A-8 illustrate various permutations in which the components of the previously described load control system are positioned at different locations with respect to each other. FIG. 7A shows an embodiment in which the load control module 704 is coupled to the associated load 712. Though not shown, it will be appreciated that the access control module may be located within the housing 708. In this permutation, the associated load 712 may include a plug-and-play arrangement. That is, by having the load control module 704 coupled to the associated load 712, the load may readily be relocated. For example, if a lamp was the associated load, the plug-and-play arrangement can enable a user to move the lamp from one electrical outlet to another without affecting the ability to control the lamp at, or proximate to, the housing (and access control module).

FIG. 7B shows an embodiment in which the associated load 762, the housing 758, and the load control module 754 are all positioned separately from each other. Though not shown, it will be appreciated that the access control module may be located within the housing 758. This permutation may illustrate embodiments in which the load control module 754 is added to control an associated load 762 installed prior to the load control module 754. This arrangement may allow a load control module 754 and a housing 758 (with access control module) to be retrofitted to monitor or control any previously installed associated load 762. For example, it may be simpler to access the power supply wiring of a fan instead of the fan itself. By coupling the load control module 754 to the power supply wiring of the fan, the installation of the load control system can be greatly simplified.

FIG. 8 shows an embodiment in which the associated load 862 is separated from the housing 858, and the load control module 854 is coupled to the associated load 862. This embodiment may illustrate an application in which the associated load 862 is in a remote location such that a user, positioned adjacent to the housing 858, cannot determine the state of the associated load 862 absent the one or more load status indicators 116. In the depicted embodiment, the associated load 862 and the housing 858 may be located in separate rooms, or the load may be positioned within a duct such as where the load is a fan.

It will be appreciated that the disclosed system can be used to control a single load, or it can be used to control multiple connected loads. In addition, a user could employ multiple different access tokens to operate multiple different loads using a single access control module.

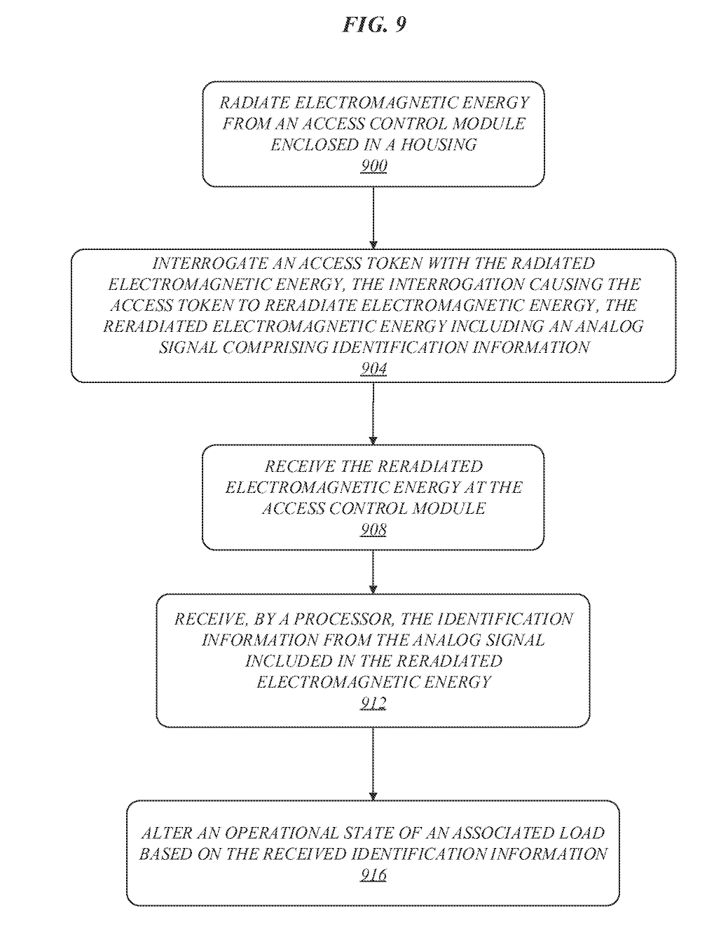

Referring now to FIG. 9, an exemplary method of controlling a load will be described in greater detail. At step 900, an access control module enclosed in a housing can radiate electromagnetic energy. In some embodiments, the electromagnetic energy is radiated in response to activation of a motion sensor. At step 904, the radiated electromagnetic energy can interrogate an access token. The interrogation may cause the access token to reradiate electromagnetic energy. The reradiated electromagnetic energy may include an analog signal comprising identification information. At step 908, the access control module can receive reradiated electromagnetic energy.

At step 912, a processor may receive the identification information from the analog signal included in the reradiated electromagnetic energy (other embodiments may employ other suitable elements in addition to, or instead of, the processor). In some embodiments, the processor may validate the received identification information by comparing the received identification information with contents of an authorization data structure. In one non-limiting exemplary embodiment, the authorization data structure may comprise a plurality of entries with each of the plurality of entries associated with a unique identifier. In some embodiments, the associated load may comprise a plurality of associated loads and each of the unique identifiers can be associated with at least one of the plurality of associated loads. In one non-limiting embodiment, instructions can be received from a user interface to add, remove, or alter the contents of the authorization data structure. At step 916, an operational state of an associated load may be altered based on the received identification information.

Some embodiments of the disclosed device may be implemented, for example, using a storage medium, a computer-readable medium or an article of manufacture which may store an instruction or a set of instructions that, if executed by a machine (i.e., processor or microcontroller), may cause the machine to perform a method and/or operations in accordance with embodiments of the disclosure. Such a machine may include, for example, any suitable processing platform, computing platform, computing device, processing device, computing system, processing system, computer, processor, or the like, and may be implemented using any suitable combination of hardware and/or software. The computer-readable medium or article may include, for example, any suitable type of memory unit, memory device, memory article, memory medium, storage device, storage article, storage medium and/or storage unit, for example, memory (including non-transitory memory), removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions may include any suitable type of code, such as source code, compiled code, interpreted code, executable code, static code, dynamic code, encrypted code, and the like, implemented using any suitable high-level, low-level, object-oriented, visual, compiled and/or interpreted programming language.

While certain embodiments of the disclosure have been described herein, it is not intended that the disclosure be limited thereto, as it is intended that the disclosure be as broad in scope as the art will allow and that the specification be read likewise. Therefore, the above description should not be construed as limiting, but merely as exemplifications of particular embodiments. Those skilled in the art will envision additional modifications, features, and advantages within the scope and spirit of the claims appended hereto.

What is claimed is:

1. A load control system, comprising:
an access token;
an access control module, the access control module is enclosed in a housing; and
a load control module,
wherein the access token is configured to wirelessly communicate identification information to the access control module, wherein the access control module is configured to receive the identification information from the access token and validate the identification information, the access control module communicatively coupled with the load control module, and
wherein the load control module is configured to control an operational state of an associated load and to enable the access token, upon validation of the identification information, to cause the operational state of the associated load to be altered, the load control module communicatively coupled with the access control module.

2. The load control system of claim 1, comprising:
a management module for validating the identification information at least in part by comparing the identification information to contents of an authorization data structure, the contents of the authorization data structure comprising a plurality of valid sets of identification information.

3. The load control system of claim 2, the management module for receiving instructions from a user interface to add or remove at least one of the plurality of valid sets of identification information in the authorization data structure.

4. The load control system of claim 2, the management module for associating a time with the identification information to create a data entry in an access history data structure each time the access token communicatively couples with the access control module.

5. The load control system of claim 1, the access control module comprising a load status indicator, the load status indicator for communicating the state of the associated load in at least one of a visual, auditory, or tactile manner.

6. The load control system of claim 1, the access token for wirelessly communicating the identification information to the access control module at least in part through energy received from the access control module.

7. The load control system of claim 1, the housing comprising a tamper resistant housing.

8. The load control system of claim 1, wherein the load control module comprises a plurality of load control modules, the access control module and the plurality of load control modules are configured to communicate through a local area network (LAN), wherein each of the plurality of load control modules is assigned a unique identifier.

9. A wirelessly controlled load control device comprising:
a housing including an access control module disposed therein, the access control module configured to control an operational state of an associated load;
an access token associated with a user, wherein the access control module is wirelessly communicable with the access token; and
a load status indicator associated with the housing, the load status indicator for indicating the operational state of the associated load.

10. The wirelessly controlled load control device of claim 9, further comprising:
a processor, wherein the processor is configured to receive identification information from the access token and determine if the user is an authorized user by comparing the identification information to contents of an authorization data structure.

11. The wirelessly controlled load control device of claim 9, the load status indicator comprising a user interface to enable the access control module to receive input from the user.

12. The wirelessly controlled load control device of claim 11, the user interface comprising a screen to display the state of the associated load.

13. The wirelessly controlled load control device of claim 9, the housing comprising at least one of a port, a door, an opening, or a plurality of assembly pieces.

14. The wirelessly controlled load control device of claim 9, the housing comprising a tamper resistant housing.

15. A method for wirelessly controlling the operational state of a load, comprising:
radiating electromagnetic energy from an access control module enclosed in a housing;
interrogating an access token with the radiated electromagnetic energy, the interrogating causing the access token to reradiate electromagnetic energy, the reradiated electromagnetic energy including an analog signal comprising identification information;
receiving the reradiated electromagnetic energy at the access control module;
receiving, by a processor, the identification information from the analog signal included in the reradiated electromagnetic energy; and
altering an operational state of an associated load based on the received identification information.

16. The method of claim 15, comprising radiating electromagnetic energy from the access control module in response to activation of a motion sensor.

17. The method of claim 15, comprising validating the received identification information by comparing, by the processor, the received identification information with contents of an authorization data structure.

18. The method of claim 17, the contents of the authorization data structure comprising a plurality of entries, each of the plurality of entries associated with a unique identifier.

19. The method of claim 18, the associated load comprising a plurality of associated loads, and each of the unique identifiers associated with at least one of the plurality of associated loads, the authorization data structure correlating the plurality of associated loads and the unique identifiers.

20. The method of claim 19, comprising receiving instructions from a user interface to add, remove, or alter the contents of the authorization data structure.
